(19) United States
(12) Patent Application Publication
(10) Pub. No.: US 2019/0189205 A1
(43) Pub. Date: Jun. 20, 2019

(54) RESISTIVE MEMORY APPARATUS AND LINE SELECTION CIRCUIT THEREOF

(71) Applicant: SK hynix Inc., Icheon-si Gyeonggi-do (KR)

(72) Inventors: Jeong Ho YI, Icheon-si Gyeonggi-do (KR); Min Chul SHIN, Icheon-si Gyeonggi-do (KR)

(73) Assignee: SK hynix Inc., Icheon-si Gyeonggi-do (KR)

(21) Appl. No.: 16/283,391

(22) Filed: Feb. 22, 2019

Related U.S. Application Data
(63) Continuation of application No. 15/385,067, filed on Dec. 20, 2016.

(30) Foreign Application Priority Data
Sep. 19, 2016 (KR) 10-2016-0119095

(51) Int. Cl. G11C 13/00; G11C 8/10

(52) U.S. Cl. CPC G11C 13/0023; G11C 13/0033; G11C 2213/71; G11C 2213/72; G11C 8/10

(57) ABSTRACT

A resistive memory apparatus includes a memory cell array, a local switch, and a global switch. The memory cell array may include a plurality of resistive memory cells coupled to a plurality of connection lines. The local switch may select a target connection line coupled to a target memory cell and a preset number of connection lines adjacent to the target connection line according to a signal obtained by decoding an address. The global switch may apply a preset level of voltage to the selected adjacent connection lines according to the signal obtained by decoding the address.

### CROSS-REFERENCES TO RELATED APPLICATION

The present application is a continuation application of Ser. No. 15/385,067, filed on Dec. 20, 2016, titled “RESISTIVE MEMORY APPARATUS AND LINE SELECTION CIRCUIT THEREOF”, which is incorporated herein by reference in its entirety.

### BACKGROUND

### 1. Technical Field

Various embodiments may generally relate to a semiconductor memory apparatus, and, more particularly, to a resistive memory apparatus and a line selection circuit thereof.

### 2. Related Art

Semiconductor memory manufacturers are offering highly integrated, low-power-consumption semiconductor memory apparatuses.

With an increase in a memory capacity of the semiconductor memory apparatus, a memory cell size and a spacing between adjacent memory cells continue to decrease. The spacing between adjacent interconnects coupled to the memory cells continues to decrease, and thus a parasitic capacitance between the interconnects and a capacitive coupling caused by the parasitic capacitance increase.

Operating voltages that are used to access memory cells during read and write operations decrease with the growth in demand for the low-power-consumption semiconductor memory apparatus.

The capacitive coupling between the interconnects may lead to a decrease in read and write margins of the low power semiconductor memory apparatus, and this may cause errors during the read and write operations.

### SUMMARY

In an embodiment of the present disclosure, a resistive memory apparatus may include a memory cell array including a plurality of resistive memory cells coupled to a plurality of connection lines; a plurality of connection line groups in each of which a preset number of adjacent connection lines are grouped; plurality of local switches connected to each of the plurality of connection lines; a plurality of local switch groups in each of which the local switches included in a same connection line group are grouped; a plurality of global switches in each of which coupled in common to one or more local switches selected from each of the plurality of local switch groups; a first decoder configured to generate a local switch selection signal by decoding a portion of an address; a second decoder configured to generate a global switch selection signal by decoding another portion of the address used for generating the local switch selection signal; and wherein, the local switches included in a same local switch group are driven in response to the same local switch selection signal; a plurality of global switches are driven in response to the global switch selection signal; one of the plurality of connection line groups is selected by the local switch selection signal, and a selected connection line included in a selected connection line group is configured to be biased to a preset a first level of voltage by the global switch selection signal, and unselected connection lines included in the selected connection line group is configured to be biased to a preset a second level of voltage by the global switch selection signal.

In an embodiment of the present disclosure, a line selection circuit may include a first decoder configured to generate a local switch selection signal by decoding a portion of an address; a second decoder configured to generate a global switch selection signal by decoding another portion of the address used for generating the local switch selection signal; a plurality of local switch groups including a plurality of local switches coupled respectively to each of a corresponding connection line of a plurality of connection line groups in each of which a preset number of adjacent connection lines are grouped; a plurality of global switch circuits which are driven in response to the global switch selection signal and are coupled in common to one or more local switches selected from each of the plurality of local switch groups; and wherein, the local switches connected to a same connection line group are driven in response to the same local switch selection signal; one of the plurality of connection line groups is selected by the local switch selection signal, and a selected connection line included in a selected connection line group is configured to be biased to a preset a first level of voltage by the global switch selection signal, and unselected connection lines included in the selected connection line group is configured to be biased to a preset a second level of voltage by the global switch selection signal.

These and other features, aspects, and embodiments are described below in the section entitled “DETAILED DESCRIPTION”

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a diagram illustrating an example of a resistive memory apparatus according to an embodiment of the present disclosure;

FIG. 2 is a diagram illustrating examples of row and column selection circuits according to an embodiment of the present disclosure;

FIG. 3 is a diagram illustrating an example of an operation of a resistive memory apparatus according to an embodiment of the present disclosure;

FIG. 4 is a diagram illustrating an example of a memory cell array according to an embodiment of the present disclosure;

FIGS. 5 and 6 are diagrams illustrating examples of unit memory cell arrays according to embodiments of the present disclosure;

FIG. 7 is a diagram illustrating an example of a memory cell array according to an embodiment of the present disclosure;

FIG. 8 is a diagram illustrating an example of a line selection circuit according to an embodiment of the present disclosure;

FIG. 9 is a diagram illustrating an example of a local switch group according to an embodiment of the present disclosure; and

FIG. 10 is a diagram illustrating an example of a global switch group according to an embodiment of the present disclosure.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

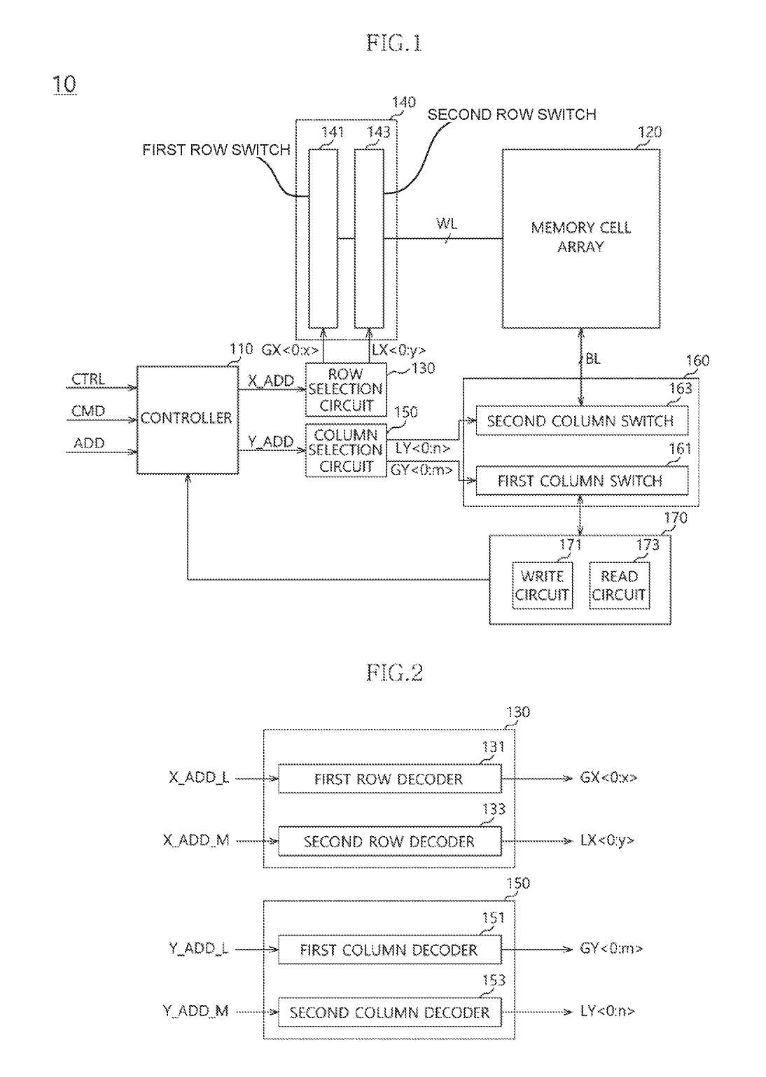

FIG. 1 is a diagram illustrating an example of a resistive memory apparatus according to an embodiment.

Referring to FIG. 1, a resistive memory apparatus 10 according to an embodiment may include a controller 110, a memory cell array 120, a row selection circuit 130, a row switch 140, a column selection circuit 150, a column switch 160, and a read and write circuit 170.

The controller 110 may control an overall operation of the resistive memory apparatus 10. The controller 110 may receive a control signal CTRL, a command CMD, and an address ADD from an external apparatus (not illustrated) such as a memory controller or a host apparatus. The controller 110 may generate a row address X_ADD and a column address Y_ADD from the address ADD, and may provide the row address X_ADD and the column address Y_ADD to the row selection circuit 130 and the column selection circuit 150.

The memory cell array 120 may include a plurality of memory cells coupled between a plurality of word lines and a plurality of bit lines. In an embodiment, the memory cell may be a resistive memory cell.

The plurality of word lines in the memory cell array 120 may be divided into a plurality of word line groups, and a preset number of adjacent word lines may be grouped into a word line group. The plurality of bit lines in the memory cell array 120 may be divided into a plurality of bit line groups, and a preset number of adjacent bit lines may be grouped into a bit line group. In an embodiment, the plurality of word lines in the memory cell array 120 may be divided into (y+1) word line groups, and (x+1) word lines may be grouped into a word line group. Likewise, the plurality of bit lines in the memory cell array 120 may be divided into (n+1) bit line groups, and (m+1) bit lines may be grouped into a bit line group.

The row selection circuit 130 may generate a global row switch selection signal GX<0:x> and a local row switch selection signal LX<0:y> in response to the row address X_ADD provided from the controller 110. In an embodiment, the row selection circuit 130 may generate the local row switch selection signal LX<0:y> in response to a most significant bit (MSB) signal of the row address X_ADD. In an embodiment, the row selection circuit 130 may generate the global row switch selection signal GX<0:x> in response to a least significant bit (LSB) signal of the row address X_ADD.

The row switch 140 may include a first row switch 141 and a second row switch 143.

The second row switch 143 may be driven in response to the local row switch selection signal LX<0:y>. The second row switch 143 may include a plurality of local row switches coupled to the plurality of word lines. A plurality of local row switches coupled to the same word line group may be driven in response to the same local row switch selection signal. For example, a certain bit of the local row switch selection signal LX<0:y> may be used to select a word line group, and the plurality of local row switches coupled to the word line group may be enabled in response to the certain bit of the local row switch selection signal LX<0:y>. In an embodiment, the MSB signal of the local row switch selection signal LX<0:y> may be used to select word line groups, and whether to enable a plurality of local row switches coupled to a certain word line group may be determined based on the local row switch selection signal LX<0:y> generated in response to a portion (e.g., the MSB signal) of the row address X_ADD. The plurality of local row switches coupled to each word line group may be referred to as a local row switch group.

The first row switch 141 may be driven in response to the global row switch selection signal GX<0:x>. The first row switch 141 may include a plurality of global row switches to which local row switches respectively selected from the local row switch groups are coupled in common. Word lines included in the selected word line group may be appropriately biased by the global row switch selection signal GX<0:x> generated in response to a portion of the row address X_ADD. In an embodiment, the global row switch selection signal GX<0:x> may be generated in response to the LSB signal of the row address X_ADD. For example, a target word line coupled to a memory cell targeted to be accessed may be biased to a preset level of voltage, and one or more word lines adjacent to the target word line may be biased to a preset level of voltage.

The column selection circuit 150 may generate a global column switch selection signal GY<0:m> and a local column switch selection signal LY<0:n> in response to the column address Y_ADD provided from the controller 110. In an embodiment, the column selection circuit 150 may generate the local column switch selection signal LY<0:n> in response to a MSB signal of the column address Y_ADD. In an embodiment, the column selection circuit 150 may generate the global column switch selection signal GY<0:m> in response to a LSB signal of the column address Y_ADD.

The column switch 160 may include a first column switch 161 and a second column switch 163.

The second column switch 163 may be driven in response to the local column switch selection signal LY<0:n>. The second column switch 163 may include a plurality of local column switches coupled to the plurality of bit lines. A plurality of local column switches coupled to the same bit line group may be driven in response to the same local column switch selection signal. For example, a certain bit of the local column switch selection signal LY<0:n> may be used to select a bit line group, and the plurality of local column switches coupled to the bit line group may be enabled in response to the certain bit of the local column switch selection signal LY<0:n>. In an embodiment, the MSB signal of the local column switch selection signal LY<0:n> may be used to select bit line groups, and whether to enable a plurality of local column switches coupled to a certain bit line group may be determined based on the local column switch selection signal LY<0:n> generated in response to a portion (e.g., the MSB signal) of the column address Y_ADD. The plurality of local column switches coupled to each bit line group may be referred to as a local column switch group.

The first column switch 161 may be driven in response to the global column switch selection signal GY<0:m>. The first column switch 161 may include a plurality of global column switches to which local column switches respectively selected from the local column switch groups are coupled in common. The number of global column switches may correspond to the number of local column switches included in the local column switch group. Accordingly, bit lines included in the selected bit line group may be appropriately biased by the global column switch selection signal GY<0:m> generated in response to a portion (e.g., the LSB signal) of the column address Y_ADD. For example, a bit line to which a memory cell to be accessed is coupled and a bit line adjacent to the bit line may be biased to a preset level of voltage.

The read and write circuit 170 may include a write circuit 171, which is used to write data in the memory cell array 120 according to control of the controller 110, and a read circuit 173, which is used to read data from the memory cell array 120 according to control of the controller 110.

When the memory cell array 120 is accessed for the write operation and the read operation, the local row and column switch selection signals LX<0:y> and LY<0:n> may be generated in response to certain portions (e.g., the MSB signals) of the row and column addresses X_ADD and Y_ADD, and a specific word line group and a specific bit line group may be selected according to the local row and column switch selection signals LX<0:y> and LY<0:n>. The global row and column switch selection signals GX<0:x> and GY<0:m> may be generated in response to certain portions (e.g., the LSB signals) of the row and column addresses X_ADD and Y_ADD, and word lines and bit lines included in the selected word line group and bit line group may be biased to a desired level of voltage according to the global row and column switch selection signals GX<0:x> and GY<0:m>.

In FIG. 1, the word line and the bit line may be referred to as a connection line, and the word line group and the bit line group may be referred to as a line group. The first row switch 141 and the first column switch 161 may be referred to as a global switch, and the second row switch 143 and the second column switch 163 may be referred to as a local switch.

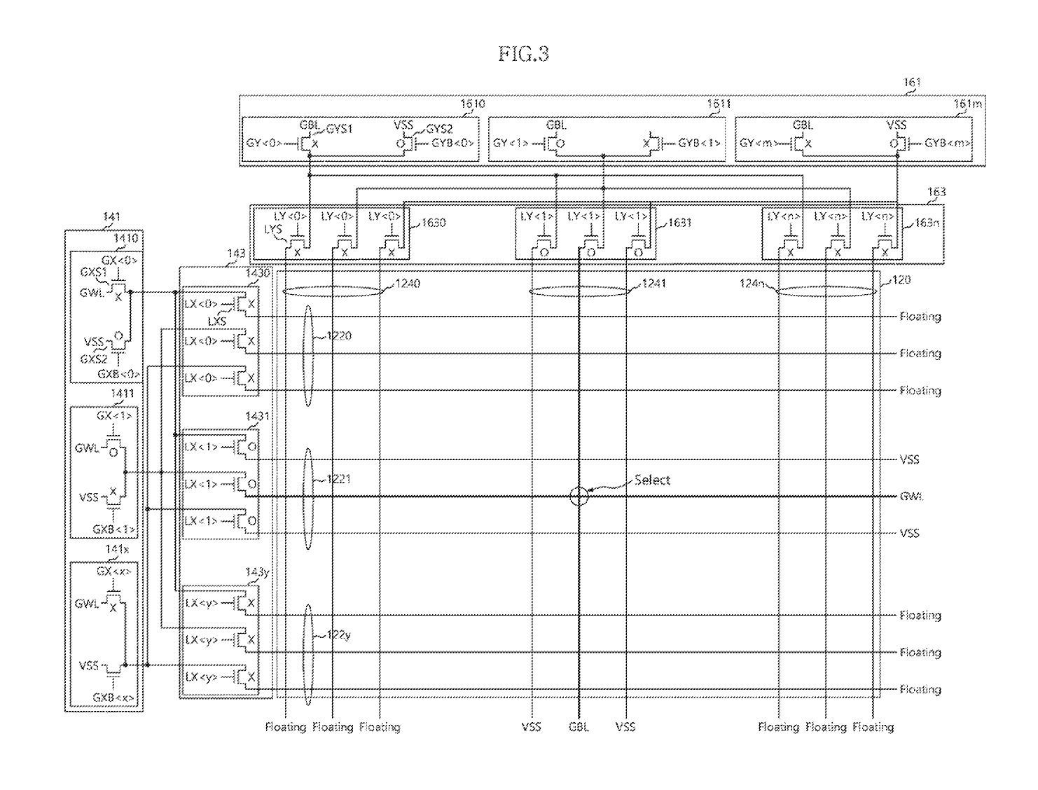

FIG. 2 is a diagram illustrating examples of a row selection circuit and a column selection circuit according to an embodiment.

Referring to FIG. 2, the row selection circuit 130 may include a first row decoder 131 and a second row decoder 133. The column selection circuit 150 may include a first column decoder 151 and a second column decoder 153.

The first row decoder 131 may generate the global row switch selection signal GX<0:x> in response to a portion X_ADD_L of the row address X_ADD. The second row decoder 133 may generate the local row switch selection signal LX<0:y> in response to another portion X_ADD_M of the row address X_ADD. The portion X_ADD_L of the row address X_ADD may be, for example, the LSB signal of the row address X_ADD. The other portion X_ADD_M of the row address X_ADD may be, for example, the MSB signal of the row address X_ADD.

The first column decoder 151 may generate the global column switch selection signal GY<0:m> in response to a portion Y_ADD_L of the column address Y_ADD. The second column decoder 153 may generate the local column switch selection signal LY<0:n> in response to another portion Y_ADD_M of the column address Y_ADD. The portion Y_ADD_L of the column address Y_ADD may be, for example, the LSB signal of the column address Y_ADD. The other portion Y_ADD_M of the column address Y_ADD may be, for example, the MSB signal of the column address Y_ADD.

When a specific memory cell is targeted to be accessed, a preset level of voltage may be applied to a bit line and a word line coupled to the target memory cell. When bit lines and word lines coupled to the target memory cell and adjacent memory cells thereto are floating, a deterioration of data signals may be caused by a coupling between the bit lines and word lines.

In an embodiment, when the target memory cell is accessed, one of the plurality of connection line groups (word line groups/bit line groups) may be selected based on at least one bit (e.g., the MSB signal) of the address signal (row address/column address). A preset level of voltage applied to the connection lines (bit line/word line) included in the selected connection line group based on the LSB signal of the address signal (row address and column address) may prevent or reduce capacitive coupling between the connection lines.

FIG. 3 is a diagram illustrating an example of an operation of a resistive memory apparatus according to an embodiment.

Referring to FIG. 3, the first row switch 141 may include a plurality of global row switch groups 1410 to 141x. The second row switch 143 may include a plurality of local row switch groups 1430 to 143y. The first column switch 161 may include a plurality of global column switch groups 1610 to 161m. The second column switch 163 may include a plurality of local column switch groups 1630 to 163n.

The plurality of word lines WL may be divided into a plurality of word line groups, and a preset number of adjacent word lines may be grouped into a word line group. For example, the plurality of word lines WL may be grouped into a plurality of word line groups 1220 to 122y, each of which includes the preset number of adjacent word lines. The plurality of bit lines BL may be divided into a plurality of word line groups, and a preset number of adjacent bit lines may be grouped into a bit line group. For example, the plurality of bit lines BL may be grouped into a plurality of bit line groups 1240 to 124n, each of which includes the preset number of adjacent bit lines.

Local row switches LXS constituting the plurality of local row switch groups 1430 to 143y may be coupled to corresponding word lines WL, and may be driven in response to the local row switch selection signal LX<0:y>. The local row switches LXS coupled to the same word line group may be controlled by the same local row switch selection signal LX<0:y>.

Each of the plurality of global row switch groups 1410 to 141x may include a global row switch GXS1 driven in response to the global row switch selection signal GX<0:x> and a bias switch GXS2 driven in response to an inverting signal GXB<0:x> of the global row switch selection signal GX<0:x>. Local row switches LXS respectively selected between the local row switch groups 1430 to 143y may be coupled in common to the global row switch GXS1 of a corresponding global row switch group.

Each of local column switches LYS constituting the plurality of local column switch groups 1630 to 163n may be coupled to a corresponding bit line, and may be driven in response to the local column switch selection signal LY<0:n>. The local column switch LYS coupled to the same bit line group may be controlled by the same local column switch selection signal LY<0:n>.

Each of the plurality of global column switch groups 1610 to 161x may include a global column switch GYS1 driven in response to the global column switch selection signal GY<0:m> and a bias switch GYS2 driven in response to an inverting signal GYB<0:m> of the global column switch selection signal GY<0:m>. Local column switches LYS respectively selected between the local column switch groups 1630 to 163y may be coupled in common to the global column switch GYS1 of a corresponding global column switch group.

An example where a certain memory cell Select (x=1, y=1: m=1, n=1) is accessed will be discussed here.

The word line group 1221 may be selected based on the local row switch selection signal LX<0:y> generated by decoding a portion of the row address X_ADD, and the bit line group 1241 may be selected based on the local column switch selection signal LY<0:n> generated by decoding a portion of the column address Y_ADD. Accordingly, a plurality of memory cells coupled between the selected word line group 1221 and the selected bit line group 1241 may be electrically coupled to word lines of the selected word line group 1221 and bit lines of the selected bit line group 1241.

The word lines included in the word line group 1221 selected based on the global row switch selection signal GX<0:x> generated by decoding another portion of the row address X_ADD may be biased. For example, the word line coupled to the access target memory cell and a word line adjacent thereto may be biased to the preset level of voltage. In an embodiment, the word line of the access target memory cell may be biased to a global word line voltage GWL and the word line adjacent thereto may be biased to a ground voltage VSS.

The bit lines included in the bit line group 1241 selected by the global column switch selection signal GY<0:m> generated by decoding another portion of the column address Y_ADD may be biased. For example, the bit line coupled to the access target memory cell and a bit line adjacent thereto may be biased to a preset level of voltage. In an embodiment, the bit line of the access target memory cell may be biased to a global bit line voltage GBL and the adjacent bit line may be biased to the ground voltage VSS.

The non-selected word line group and the non-selected bit line group may be in a floating state.

Accordingly, the coupling between adjacent interconnects may be prevented or reduced by applying the preset level of voltages GWL and GBL to the word line and the bit line of the access target memory cell and biasing the adjacent word line and the adjacent bit line with the preset level of voltage (e.g., ground voltage VSS).

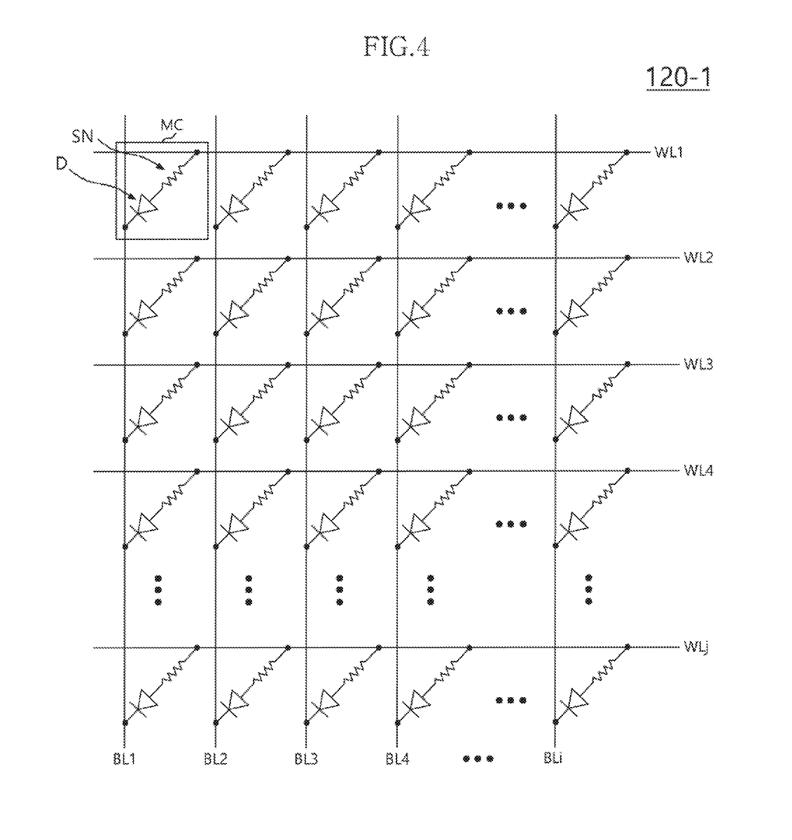

FIG. 4 is a diagram illustrating an example of a memory cell array according to an embodiment.

Referring to FIG. 4, the memory cell array 120-1 may be a horizontal structure two-dimensional (2D) memory, and may include a plurality of word lines WL1 to WLj, a plurality of bit lines BL1 to BLi, and a plurality of memory cells MC.

Each of the plurality of memory cells MC may include a data storage node SN and a selection element D. The data storage node SN may contain a resistive variable material, and the selection element D may be a switching element.

The memory cell MC may be coupled between the word line WL and the bit line BL. The data storage node SN and the selection element D may be coupled to the word line WL, and the selection element D may be coupled to the bit line BL. Alternatively, the data storage node SN may be coupled to the bit line BL, and the selection element D may be coupled to the word line WL.

The resistive variable material constituting the data storage node SN may include a phase-change material, which can change its phase from crystalline to amorphous phase or vice versa and/or can change its resistance according to a current amount flowing therethrough. In an embodiment, the data storage node SN may include a perovskite compound, a transition metal oxide, a magnetic material, a ferromagnetic material, or antiferromagnetic material.

The selection element D may control a current supply to the data storage node SN according to the voltages applied to the word line and the bit line coupled to the selection element D. In an embodiment, the selection element D may be, for example, a diode.

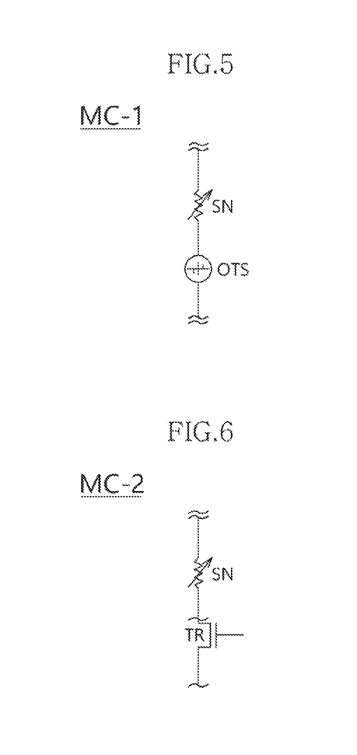

FIGS. 5 and 6 are diagrams illustrating examples of a unit memory cell according to embodiments.

FIG. 5 illustrates an example of a memory cell MC-1 in which a storage node SN and a selection element OTS are coupled in series. In an embodiment, the selection element OTS may be an ovonic threshold (OTS) switching element.

FIG. 6 illustrates an example of a memory cell MC-2 in which a storage node SN and a selection element TR are coupled in series. In an embodiment, the selection element TR may be a MOS transistor, for example, a vertical channel transistor.

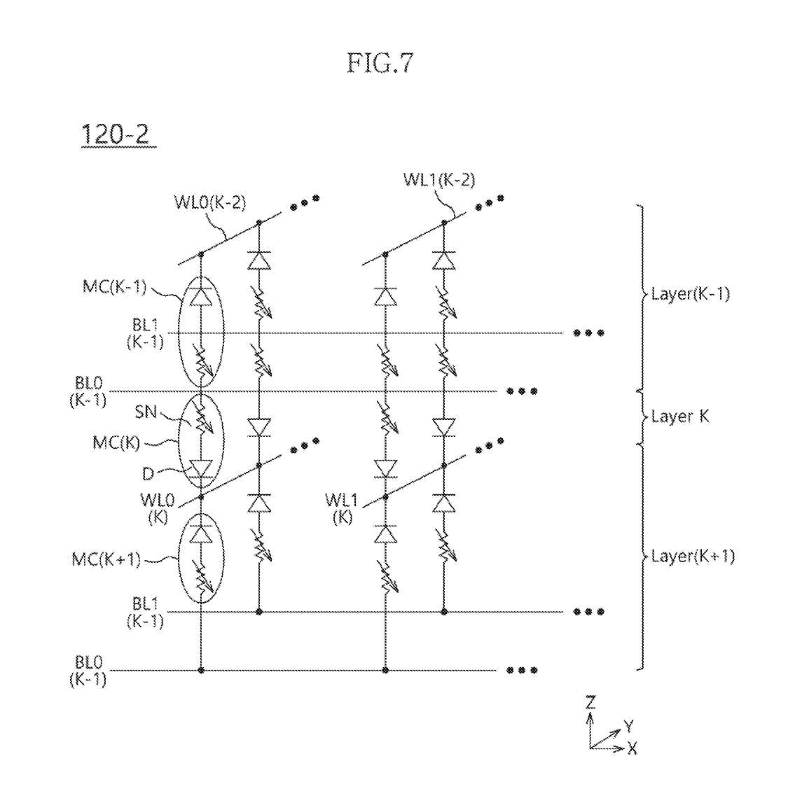

FIG. 7 is a diagram illustrating an example of a memory cell array according to an embodiment.

Referring to FIG. 7, a memory cell array 120-2 according to an embodiment may have a 3D structure. FIG. 7 illustrates a portion of the memory cell array where layers on an X-Y plane are stacked in a Z-axis direction. In an embodiment, the X-axis may be a direction in which the bit line extends, and the Y-axis may be a direction in which the word line extends. The Z-axis may be a stacking direction in which the layers are stacked.

The plurality of memory cells MC coupled between a word line WL and a bit line BL may be included each layer Layer (K−1), Layer K, and Layer (K+1). The memory cell MC may have a structure that couples a data storage node and a selection element to each other. The data storage node may be formed using a resistive variable material, and the selection element may be implemented using any one selected from various switching elements such as a diode, an OTS switching element, and a transistor.

In the layer Layer (K−1), Layer K, and Layer (K+1), the word line WL and the bit line BL may be arranged along the stacking direction of the layers, and the data storage node SN and the selection element D of the memory cell MC may be vertically arranged along the stacking direction.

In an embodiment, the adjacent layers Layer (K−1), Layer K, and Layer (K+1) may share the word line or the bit line.

In an embodiment, each two adjacent memory cells of adjacent layers may form a symmetric structure about a signal line disposed therebetween.

When a word line and a bit line are selected to access a certain memory cell MC, a certain word line group and a certain bit line group may be selected, and the selected word line group and the bit line group may be appropriately biased as described above with reference to FIGS. 1 and 2. Accordingly, the coupling may be prevented or reduced.

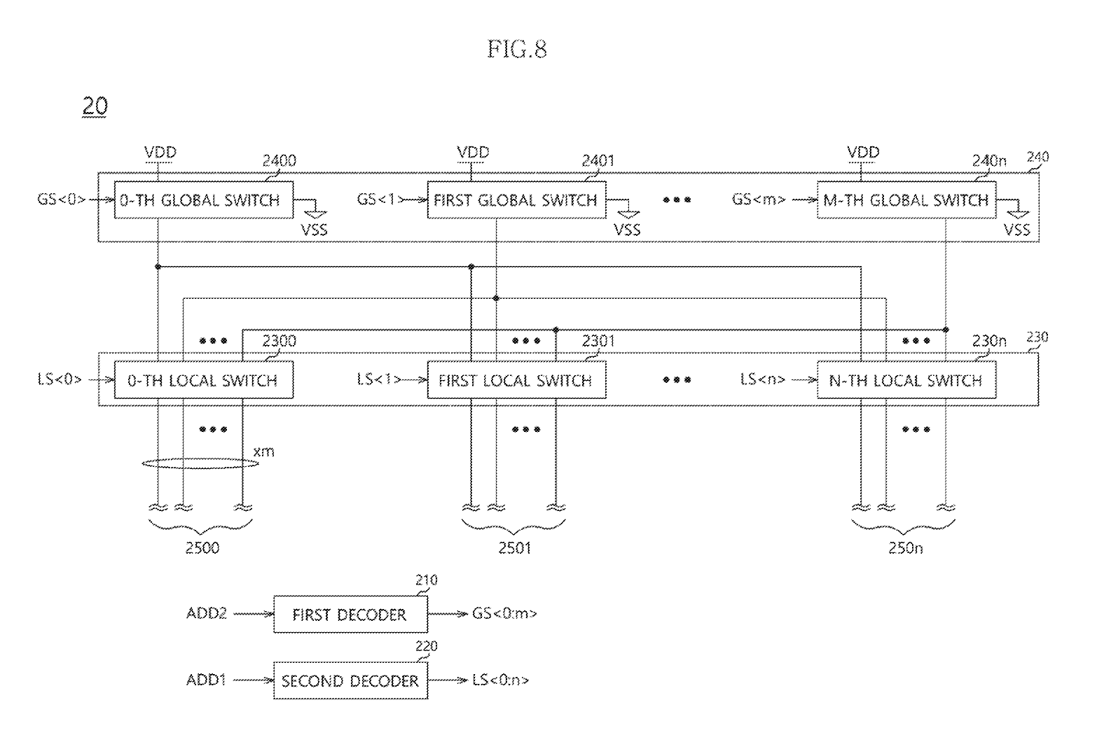

FIG. 8 is a diagram illustrating an example of a line selection circuit according to an embodiment.

Referring to FIG. 8, a line selection circuit 20 according to an embodiment may include a first decoder 210, a second decoder 220, a local switch circuit 230, and a global switch circuit 240.

The first decoder 210 may generate a global switch selection signal GS<0:m> in response to a portion ADD2 of an address signal.

The second decoder 220 may generate a local switch selection signal LS<0:n> in response to another portion ADD1 of the address signal.

The address signal may be, for example, a row address signal or a column address signal, but the address signal is not limited thereto. In an embodiment, the portion ADD2 of the address signal may be a LSB signal of the address signal, and the other portion ADD1 of the address signal may be a MSB signal of the address signal.

The local switch circuit 230 may include a plurality of local switch groups 2300 to 230n. Each of the local switch groups 2300 to 230n may include a plurality of local switches driven in response to a local switch selection signal LS<0:n> generated by the second decoder 220.

The global switch circuit 240 may include a plurality of global switch groups 2400 to 240m. Each of the global switch groups 2400 to 240m may be driven in response to the global switch selection signal GS<0:m> generated by the first decoder 210.

An interconnect 250 may be coupled to each local switch. In the interconnect 250, the preset number m of adjacent interconnects may be grouped to form a plurality of interconnect groups 2500 to 250n.

Local switches in each of the local switch groups 2300 to 230n coupled to one of the interconnect groups 2500 to 250n may be driven in response to the same local switch selection signal, for example, one bit of the local switch selection signal LS<0:n>.

Local switches respectively selected between the local switch groups 2300 to 230n may be coupled in common to the same global switch group 2400 to 240m.

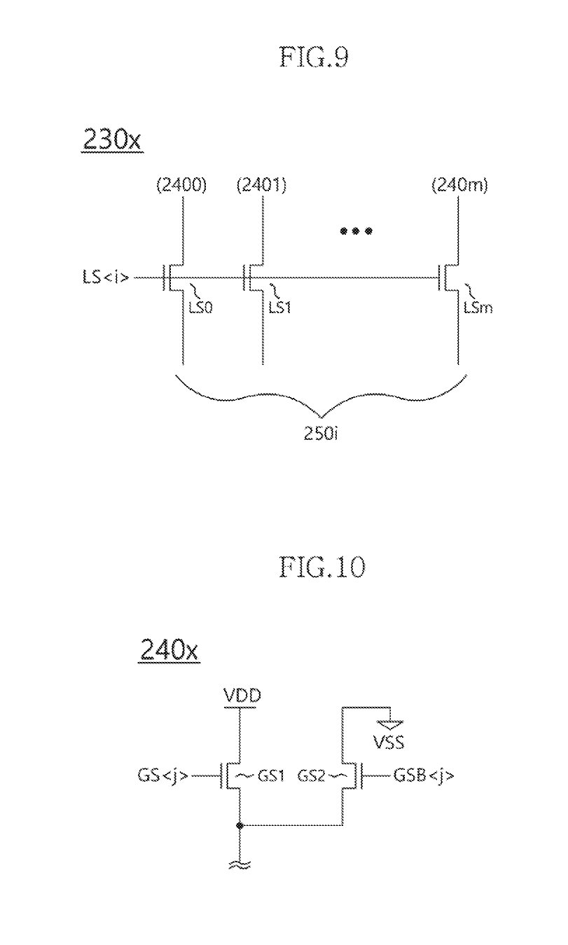

FIG. 9 is a diagram illustrating an example of a local switch group according to an embodiment.

Referring to FIG. 9, a local switch group 230x may include a plurality of local switches LS0 to LSm driven in response to a local switch selection signal LS<i>.

One ends of the local switches LS0 to LSm may be coupled to the global switch groups 2400 to 240, and the other ends of the local switches LS0 to LSm may be coupled to interconnects in a corresponding interconnect group 250i.

FIG. 10 is a diagram illustrating an example of a global switch group according to an embodiment.

Referring to FIG. 10, a global switch group 240x may include a global switch GS1 driven in response to a global switch selection signal GS<0:j> and a bias switch GS2 driven in response to an inverting signal GSB<0:i> of the global switch selection signal GS<0:j>.

A power voltage VDD may be provided to one end of the global switch GS1 and local switches respectively selected between the local switch groups 2300 to 230n may be commonly coupled to the other end of the global switch GS1. The ground voltage VSS may be supplied to one end of the bias switch GS2 and the other end of the bias switch GS2 may be coupled to the other end of the global switch GS1.

Any one of the plurality of interconnect groups 2500 to 250n may be selected in response to the local switch selection signal LS<0:n> generated from the second decoder 220. A voltage may be provided to an interconnect in the selected interconnect group 2500 to 250n in response to the global switch selection signal GS<0:m> generated by the first decoder 210. For example, the power voltage may be provided to a target interconnect, which is targeted to be accessed, and the ground voltage may be provided to an adjacent interconnect in the same interconnect group, and thus the coupling between the interconnects may be prevented or reduced.

In FIG. 8, the interconnect 250 may be the bit line or the word line of the semiconductor memory apparatus. The address signal may be the column address and the row address.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A resistive memory apparatus comprising:
a memory cell array including a plurality of resistive memory cells coupled to a plurality of connection lines;
a plurality of connection line groups in each of which a preset number of adjacent connection lines are grouped;
plurality of local switches connected to each of the plurality of connection lines;
a plurality of local switch groups in each of which the local switches included in a same connection line group are grouped;
a plurality of global switches in each of which coupled in common to one or more local switches selected from each of the plurality of local switch groups;
a first decoder configured to generate a local switch selection signal by decoding a portion of an address;
a second decoder configured to generate a global switch selection signal by decoding another portion of the address used for generating the local switch selection signal; and
wherein, the local switches included in a same local switch group are driven in response to the same local switch selection signal;
a plurality of global switches are driven in response to the global switch selection signal;
one of the plurality of connection line groups is selected by the local switch selection signal, and
a selected connection line included in a selected connection line group is configured to be biased to a preset a first level of voltage by the global switch selection signal, and unselected connection lines included in the selected connection line group is configured to be biased to a preset a second level of voltage by the global switch selection signal.

2. The resistive memory apparatus of claim 1, wherein the plurality of connection lines includes a word line, and the address includes a row address.

3. The resistive memory apparatus of claim 1, wherein the plurality of connection lines includes a bit line, and the address includes a column address.

4. The resistive memory apparatus of claim 1, wherein a portion of the address include a most significant bit (MSB) of the address.

5. The resistive memory apparatus of claim 1, wherein the other portion of the address includes a least significant bit (LSB) of the address.

6. A line selection circuit comprising:
a first decoder configured to generate a local switch selection signal by decoding a portion of an address;
a second decoder configured to generate a global switch selection signal by decoding another portion of the address used for generating the local switch selection signal;
a plurality of local switch groups including a plurality of local switches coupled respectively to each of a corresponding connection line of a plurality of connection line groups in each of which a preset number of adjacent connection lines are grouped;
a plurality of global switch circuits which are driven in response to the global switch selection signal and are coupled in common to one or more local switches selected from each of the plurality of local switch groups; and
wherein, the local switches connected to a same connection line group are driven in response to the same local switch selection signal;
one of the plurality of connection line groups is selected by the local switch selection signal, and
a selected connection line included in a selected connection line group is configured to be biased to a preset a first level of voltage by the global switch selection signal, and unselected connection lines included in the selected connection line group is configured to be biased to a preset a second level of voltage by the global switch selection signal.

7. The line selection circuit of claim 6, wherein the plurality of connection lines includes a word line, and the address includes a row address.

8. The line selection circuit of claim 6, wherein the plurality of connection lines includes a bit line, and the address includes a column address.

9. The line selection circuit of claim 6, wherein the adjacent connection lines grouped into a connection line group include a target connection line coupled to a target memory cell and a preset number of connection lines adjacent to the target connection line, and the global switch circuits apply the first level of voltage to the target connection line coupled to the target memory cell and apply a second level of voltage to the connection lines adjacent to the target connection line.
